(19) United States
(12) Patent Application Publication
(10) Pub. No.: US 2009/0092763 A1
(43) Pub. Date: Apr. 9, 2009

(54) Method and Device for Testing the Quality of a Metallic Coating

(75) Inventor: Nils Hoffmanh, Attendorn (DE)

Correspondence Address: PROSKAUER ROSE LLP, ONE INTERNATIONAL PLACE, BOSTON, MA, 02110, US

(73) Assignee: VIEGA GMBH & CO. KG, Attendorn (DE)

(21) Appl. No.: 12/282,413

(22) PCT Filed: Mar. 13, 2007
(86) PCT No.: PCT/EP2007/052365

§ 371 Date: Nov. 25, 2008

(30) Foreign Application Priority Data
Mar. 14, 2006 (DE) 10 2006 012 021.3

(51) Int. Cl. H05H 1/46; C23C 14/02; B05D 3/06; C23C 16/54

(52) U.S. Cl. 427/488; 427/569; 427/534; 427/575; 427/579; 118/723 R; 264/209.1

(57) ABSTRACT

A method and a device for coating an inner surface of a hollow endless geometry, in particular of a pipe/tube includes introducing a gas mixture comprising at least one precursor into the endless geometry, in which the endless geometry is passed through at least one electrode unit, in which an alternating electric voltage is applied to the electrode unit, so that the gas mixture inside the endless geometry is at least partially transformed into a plasma state in the region of the electrode unit. A reaction product is produced in the gas mixture from the precursor by the plasma and the reaction product is deposited on the inner surface of the endless geometry.

### CROSS-REFERENCE TO RELATED APPLICATIONS

This application is a National Phase Application of International Patent Application No. PCT/EP2007/052365, filed on Mar. 13, 2007, which claims the benefit of and priority to German Patent Application No. DE 10 2006 012 021.3-45, filed on Mar. 14, 2006, which is owned by the assignee of the instant application. The disclosure of each of these applications is incorporated herein by reference in its entirety.

### FIELD OF THE INVENTION

The invention concerns a method and an apparatus for the coating of an interior surface of a hollow, continuous, geometric array, specifically, a tube.

In the following description, the application of the invention regards, to a large extent, tubes or pipes for the transport of potable water. However, the invention is not limited to this field. Optional uses for the coating of hollow, continuous, geometric arrays can be improved by the principles of the present invention. A hollow, continuous, geometric array is not necessarily limited to the mentioned tubes and pipes, largely used for potable water, but can be inclusive of hoses, gasketed enclosures, food product conduits, lines to transport medicinal materials, catheters, and industrial piping systems. Further in this classification can be mentioned lines to conduct fuels, lubricants, high-purity gases and liquids as well as hydraulic system conductors. This listing of possible applications is not exclusive, but is presented for the sake of establishing an understanding of uses of the invention.

### BACKGROUND

In the case of all the above named applications, a common occurrence is that substances from the material of the hollow array in trace amounts may overcome phase barriers and thus become entrained in a medium in transport within the hollow array. Ideally, no such materials are expected to so diffuse, but the danger thereof should be avoided. This is particularly urgent in the case of potable water, which is bound by stringent regulations to protect against potentially dangerous substances therein. On this account, making the interior surface of the conducting tubing inert to medium reaction becomes necessary, in order to protect transported substances.

Particularly in the case of plastic tubing, which is frequently used for the transport of drinking water, the necessity of security from the entrainment or infusion of plastic additives is of high importance. These additives may include softeners and stabilizing agents, which separate from the plastic and diffuse into the carried medium, this medium being, as indicated, potable water. Likewise, care must be taken, that components of the plastic itself do not entrain themselves in the carried medium, again, particularly into potable water.

One possible solution to the above stated problems is to be found in a tube, which is furnished with a stainless steel liner. To manufacture tubes in this manner, the first requirement is that a thin walled tube of stainless steel must be obtained, and this steel tubing must be then encased by the actual plastic material of the final tube. The manufacture of such tubes has the disadvantage, that the thin stainless steel liner is very easily subjected to sharp buckling at a transverse line of bending, this buckling commonly termed a “knick”. The result of such buckling is that the entire continuous tube becomes unserviceable in its protective function. Another poor characteristic is that to avoid buckling of this type, the inner stainless steel tube may be made too thick, which precludes installations requiring sharp bending at small radii.

Additional difficulties arise in connection with the limited inside tube diameters which can be commercially obtained. The reason for this is that very small, as well as very large, cross-sections are not easily available where stainless steel tubing is concerned.

### SUMMARY OF THE INVENTION

In general, an aspect of the invention is to make available a method and an apparatus for the coating of an interior surface of a hollow, continuous, geometric array, for example a tube, which are applicable to a greater multiplicity of cross-sectional diameters. A further aspect is to overcome cited technical difficulties by furnishing a very thin liner on the inner surface of tubing, which in turn allows tube manufacture calling for very small radii of curvature.

In general, in one embodiment, the previously described technical problems can be solved, first by a method, wherein at least one gas mixture, containing a preliminary additive, is introduced into a continuous tubing system. This tubing system, i.e. the hollow, continuous, geometric array, now containing the said gas mixture, is further subjected to the influence of at least one electrode unit, which itself is electrically subjected to an alternating voltage. The result of this arrangement is that the gas mixture, in the neighborhood of the said electrode unit is fully or partially converted into a plasmatic state. Due to the now existing plasma in the tubular system, a reaction product is generated from the preliminary additive residing in the gas mixture. This reaction product, so made, deposits itself on the inside of the continuous tubular system.

In one case of an advantageous embodiment of the method, in accord with the invention, the atmosphere within the tubing system, prior to the introduction of the said gas mixture, is infused by an additive-free, i.e. an additive-poor, preliminary gas mixture. In this way, a purging of the tube system takes place by this said additive-free gas mixture, which removes preexisting atmosphere.

In one embodiment, the method includes an activation step of the inner wall of the continuous tube by means of plasma ignition, wherein the inner wall is cleaned from interfering substances. This operation is to occur during a period when the gas content of the tube system is in an additive-free (additive-poor) state. When this is done, then a possibility arises, that undesirable by-products form in the said reaction, which would obstruct, or even prevent, the expected inner wall coating reaction results.

In an embodiment, as the above procedure is carried out, it is of advantage, if the said activation of the cleaned surface, is executed as a separate work-step. In this way counter-effective chemical reactions in the presence of plasma cannot occur simultaneously.

In an embodiment of the invention, an arrangement for the creation of a desired atmosphere within the continuous tube system can be found in that, the additive-free, i.e. additive-poor, gas mixture can be introduced first as a carrier gas mixture. This allows the existing gas content to be adjusted to a desired composition. As a second step, this carrier gas is then followed by a second gas mixture carrying additive. In this way, an additive-free gas mixture need not be instantly exchanged in favor of the additive containing gas mixture. However, this method of operation is limited to use only in short runs of a continuous tubing system, since arrays of excessive length cannot be reliably filled with an additive-free gas mixture and then subsequently uniformly exchanged in favor of the additive carrying gas mixture.

Where “plasma” is concerned, as mentioned in the above description of the method, a gaseous state is to be understood, wherein, within the treated gas, a substantial portion of free charge carrying ions and unattached electrons are present. These so charged particles are accelerated in an electric field. In this field, the free particles are brought to a high degree of activity, so that they produce more charge carrying particles, to the effect that the plasma becomes self-restoring, thereby, in effect, continually renewing itself.

A surprising aspect of the method lies therein, in that the plasma is generated in a closed system at approximately atmospheric pressure. On this account, first, an undesirable mixing with unwanted gases can not occur, such unwanted gases being, for example, ambient air, such as occurs in other atmospheric plasma applications. Second, it is not necessary to evacuate the volume in which the mix takes place, in order to produce a low pressure plasma. In the case of the hollow, continuous, geometric array, that is, by example, an extended tube system, such an evacuation could only be made by the expenditure of substantial effort and cost. Since hollow, continuous runs of tubing, for example, are manufactured in lengths exceeding thousands of meters, such lengths would require extensive internal coating with inert, particulate migration obstructing material.

There are, fundamentally, various possibilities for producing a plasma within the hollow interior of a continuous tubing system. For example, two possibilities will be designated below, which for example, vary from one another in the characteristics of the voltage which is applied to the therewith associated electrode unit.

In a first instance, a microwave discharge can be effected, whereby a microwave emission in the range of 1 MHz to several GHz are produced. By means of the energy which is associated with the microwave radiation within the hollow space, the charged and polarized gas particles, i.e. the atoms, molecules, ions, electrons, are activated into strong vibratory states, which lead to a far reaching ionization and an excitation of the gas mixture. In a typical manner, in this procedure no discharge sparking occurs nor do streamers exist, since the frequencies employed are too high to permit the generation of such displays. The associated excitation energy is accordingly diverted to the conversion of additives which are entrained in reaction products, which can then, in turn, deposit themselves on the inner surface of the tubing system as a coating, that is to say, complete the reaction or enhance and polymerize the present coating.

Alternately, a dielectrically retarded discharge or a barrier discharge, which latter is also described as a corona discharge, can be employed to induce the above reaction. For such an operation, material of a plastic tube itself can serve as the dielectric or as a barrier. Voltage, varying in time periods, is provided with a frequency, which frequency within the hollow space, can exhibit itself at 50 to 60 Hz (as in keeping with utility service) or, on occasion, be raised to exceed 100 kHz. The adjustment of the voltage itself is governed on a case to case basis, dependent upon the physical geometry of the tubular system and in regard to additional pertinent conditions. However, during a use of barrier discharge in a hollow, continuous, geometric array, that is, in an inner tube space, discharge sparks and/or streamers can generate individually or in tuft form. These discharges aid in converting the additive or additives in the residing gas mixture (at least partially) into a plasma state. The conversion of the additive or additives into the reaction product which is to coat the inner wall surface, that is, into a “reactive species”, does form the reaction product by the described deposition reaction. This reaction occurs as a result of the chemical interaction of the gas mixture with the mentioned streamers themselves and/or interaction with the multitude of basic gas elements such as, the above mentioned atoms, molecules, fragmented molecules, ions, and electrons.

Associated herewith, preference is given to so adjusting the plasma, that the difference in contained energy of the said atoms, molecules and ions remains less than that of the electrons. In other words, this may be called a thermal imbalance. Correspondingly then, the non-thermal plasmas can be preferred, because these plasma do not attack the material of the continuous geometry, i.e. of the tubing. Nevertheless, it is possible to make use of thermal plasmas, under circumstances wherein the operational conditions of the plasmas are so adjusted, that no damage to the said material of the tubing can be expected. As an example, to carry this out successfully, it is possible that the reaction speed can be so governed that the duration of activity of the plasma is kept as low as possible.

The previously described electrically alternating voltages, that is, the electrical fields are likewise time related and can serve as:
a) alternating voltage,
b) voltage values with alternating prefixes,
c) time-related varying direct current,
d) or voltage values of the same prefix.
   The character of time-change is likewise a variable. On this account, sine-wave voltage curves, pulsated voltage curves or combinations thereof can be applied.

Previously, the electrode unit has been described without detail. More closely explained, these units, in accordance with the invention, can possess a multiplicity of voltage carrying electrodes. Seen as advantageous, is a situation, for example, wherein an electrode unit incorporates at least two electrodes, which embrace the hollow, continuous, geometric array, this being, for instance, tubing, from both ends. Thus an unbroken distance spatially exists between the two electrodes, whereby the electrical field is in uniform force throughout the hollow wall opening of the array, within which it can generate the plasma discharge. As an alternative, it is possible that the electrode unit can contain more than the said two electrodes, in order to accommodate a more complex electrical field. For example, with four electrodes, reversing electrical fields can be created, a condition which would improve the efficiency of the build-up of plasma.

In an advantageous way, a multiplicity of electrode units can be provided and the continuous tubing would run through successive electrode units. Thus, several plasmas are produced, one after the other, so that the reaction bringing about deposition need not be encumbered by thermal damage of the continuous tubing material, and contrary to other methods, the desirable thickness of wall coating can be attained. The succession of plasmas, which may be considered as each being individual, are separated, one from the other. The result of this separation is that between two successive runs of plasma, a cooling period can intervene.

With this successive arrangement, a cascade effect exists, which can be subjected to a series of electrical fields, which, in turn, can be differentiated from one another as to the arrangement of each, including voltage parameters, frequency, amplitude and phase. As an example, with this described method, the first of the successively oriented electrode units can be reserved for the ignition of the plasma and the (at least) next electrode unit can serve for the placement of a desired coating thickness by using more than one step. Likewise, as indicated above, thermal damage to the continuous run of tubing is excluded, or, at least, is minimized. At the same time, an integrally increased product deposition rate is achieved and therewith a desirable thickness of internal wall coating is attained. The number of the electrode units and their operational parameters can be made to suit each application.

In order to cause the inner surface of the tubing wall to be rendered inert, methods in accordance with the invention includes depositing a very thin layer of a passivating material on the inner surface. This layer must be of a thickness which is no more than that required to fully cover the inner wall surface of the continuous tube. Such a protective coating is not required to possess an individual, self-supporting character. On this account, the deposited layer of inert material can be considerably thinner than the conventional stainless steel tubular liner common to conventional protection.

This thin, deposited coating, because of its thinness, can be so flexible that, when bent, an improved resistance to buckling is achieved and therewith tubing turns of small radius can be effected.

The reaction product is also deposited on the wall surface of the tubing as a completely unbroken coating. The wall surface thereunder thus becomes protected by this inert layer and is sealed off from medium contact. Thus a direct interaction between the wall surface and the transported medium is avoided.

Likewise, as an alternative, it is possible that the reaction product can be deposited only on a predetermined portion of the inner surface of the continuous run of tubing. This portion could represent at least a 95% surface section, or even a 90% surface section. Smaller sections would, optionally, be possible. This embodiment of the invention would be in order, if, in the case of the application of the tubing, a total inert covering of the wall surface is not required and the remainder of the run of tubing can tolerate a direct contact between the transported medium and the inner surface of the tubing.

The gas mixture is introduced into the continuous tubing length from one end, flows through the section for plasma discharge and then flows out of the opposite end of the tubing. In this way, those reaction products of the gas mixture, which were not deposited, as well as unusable by-products of the reaction, are transported out of the system with the main gas stream.

An additional variant of the described method is that the speed of the transport of the hollow, continuous, geometric array, here a tube, through the at least one electrode unit is adjusted to be less than the flow speed of the gas mixture. Thereby, assurance is provided that in the area of the at least one electrode unit, continually a fresh, i.e., a non-reacted gas mixture is continually present and the plasma discharge can function with a uniform inflow of unconverted additives.

In an embodiment of the invention the continuous geometry, that is to say, the tube, is wrapped about a drum shaped roll, so that, the continuous hollow, continuous, geometric array, specifically, a tube system, is now fed from the interior of said drum. In this drum, for example, is arranged a small capsule, namely a bottle-like vessel, which is pressure-adapted to the gas mixture and by means of an appropriate connection, joins the continuous run of the tube array.

Another embodiment of the method is based upon that point in time when the inner surface of the tubing is made inert.

As has been disclosed above, a continuous run of tubing, during its time of formation in an extrusion press, can be subsequently conducted through at least one electrode unit station. Thus, the inner wall surface of the tubing becomes inherently inert to otherwise aggressive substances, so that a finished product is available at the conclusion of tubing manufacture.

During the course of the previously described operation concerning the method including the extrusion procedure, in some embodiments, it is of advantage, if the gas mixture is also simultaneously fed into the interior of the currently forming hollow, continuous, geometric interior array of, for example, tubing. In this case, the gas mixture finds its release, after the creation of plasma, through the opposite, open end of the finished tubing. To enable this type of production of an inherently coated tubing, following an extrusion apparatus, a hollow, a calibrated nozzle penetrates, in the presence of the above said gas mixture, the center of the extruded plastic. This coactive start of the extrusion of the tubing is particularly advantageous as it permits a direct, customized, manufacture for shorter sections of continuous tubing. These shorter sections could be considered, for example, as being 50 to 150 meters in length. In general, caution must be exercised to assure that the gas mixture pressure is not raised to such a degree, that the extruded mass of the continuous tubing bulges and in so doing, interrupts the manufacturing process.

An alternate embodiment becomes possible where the material of the tubing is cross-linked plastic. This would occur as part of the extrusion procedure during the above described simultaneous inert coating of the interior walls. To take advantage of this embodiment, as a first step, the plastic would be subjected to a hardening cure, which sets the material. This is to be done by a radiant cross-linking operation after which the gas mixture can be introduced into the tubing and conducted through an electrode unit. Thus the process for making the inner wall surface inert occurs at an early point in time at which the plastic has already assumed its final condition and only small surface deviations are possible. This alternate procedure assures a stable coating of an inert material.

In regard to the above described method, there are various gas mixture combinations, which lead to different deposition substances. In general, care must be taken in an execution of the following description, that the invented process in a constant plasma atmosphere has facets of unknown results. The reason for this is that, fragments of the additive (or additives) formed by the discharge process, as well particulates of the carrier gas, are numerous and unpredictable. These fragments have a tendency to chemically interact with one another and/or with the described particulates of the residual gas mixture. On this account, what is mentioned in the following will be principally limited to the characteristics of those materials which find employment in the invented method and of the coatings which result from their said use.

As a first alternative, a mixture first, of an inert gas or air and second, of hexamethyldisiloxane (HMDSO) or, hexamethyldisilazane (HMDSN) can be used. These gas additives enable the deposition of glassy coatings, which, due to their impervious surfaces, provide an effective barrier for a preponderance of transported media, chemical compounds and gases. The degree of stiffness, that is, resulting flexibility, can be adjusted by varying the content of oxygen in the gas mixture. Alternative to HMDSO and HMDSN could be various other silicon-containing compounds which would produce glassy deposits. As examples of these are: tetraalkoxylsilane (i.e. tetramethoxysilane, TMOS; tetraethoxysilane, TEOS), trialkoxyalkylsilane, dialkoxydialkylsilane, cyclic dimethylsiloxanoligomere (that is: D1₃, D₄) and bis (trialkoxysilyl)alkylene.

As a second example of a gas mixture, a mixture of acetylene or ethylene can be used as an agent to form an inert lining from which, with the application of the plasma, a highly cross-linked carbon layer is produced which again builds an effective barrier between the inner wall surface of the continuous run of tubing and transported media.

A third example of a gas mixture is presented by fluorine containing gases. In this case, by the fluoridation of the inner wall surface of the continuous tubing, an effective barrier layer is interposed, particularly for organic molecules from various sources.

The fourth example of a gas mixture involves a fluor-carbon type, fluorhydrocarbon containing mixture. From this additive, a fluorcarbon coating can be produced, wherein the residual valences become saturated with fluor-substitutes, whereby hydrophobic and lipophobic characterizations can be adjusted.

The above mentioned technical procedure, or method, in accordance with the invention, is achieved by means of an apparatus for the coating of an inner surface of a hollow, continuous geometric array, notably a tubular system. The apparatus possesses, in order to carry out its function, a gas entry device for feed of a gas mixture into a continuous run of tubing and possesses at least one electrode unit for the creation of an electrical field in the hollow space within said continuous, geometric array of tubing.

Embodiments of the apparatus include at least one transport device for the forward displacement of a continuous, geometric run of tubing and if desired, at least one transport device to displace the said tubing in the reverse direction. This arrangement allows a low friction forward and back movement of the continuous geometric array of tubing, in order to bring the said tubing to and/or away from any one electrode unit. In the case of an integration of the procedure into a mass production line, which would include an initial extrusion step, it is possible that the transport device can be replaced by a centrally placed, calibrated nozzle arrangement. This will relieve the overall equipment of a forward transport device of the continuous tubing. This duty would be replaced by a guidance of the moving tubing in a forward direction along with a centralization of an attendant, centrally disposed nozzle. Thus, the apparatus is now in a position to take over the above described method. The continuous tubing is then transported toward the at least one electrode unit, while the gas in-feed device adds the gas mixture from one end of the continuous tubing. In the neighborhood of the electrode unit, the gas mixture is at least partially converted to a plasma and the precipitation, or rather deposition of the reaction products from the additive or additives in the gas mixture, can take place onto the inner wall surfaces of the said continuous tubing.

### BRIEF DESCRIPTION OF THE DRAWINGS

Further embodiments and advantages of the method and apparatus are described and explained in greater detail with the aid of attendant drawings. There is shown in:

FIG. 1 a first exemplary embodiment of an invented apparatus for the coating of an inner surface of a continuous tube, presented in a schematic manner,

FIG. 2 a second exemplary embodiment of an invented apparatus for the coating of an inner surface of a continuous tube, presented in a schematic manner,

FIG. 3 a first exemplary embodiment of an electrode unit with two electrodes, shown in cross-section,

FIG. 4 a second exemplary embodiment of an electrode unit with four electrodes, shown in cross-section,

FIG. 5 cross-section of a tube rolled upon a drum with a gas inlet fitted through the drum wall,

FIG. 6 in perspective, a second embodiment of an electrode unit with two electrodes, whereby the electrodes circumferentially encompass the continuous section of tubing in order to generate a plasma between the two electrodes in a given selected section of the continuous tubing and

FIG. 7 an exemplary embodiment of a gas feeding system within an extruder for the manufacture of a plastic tube.

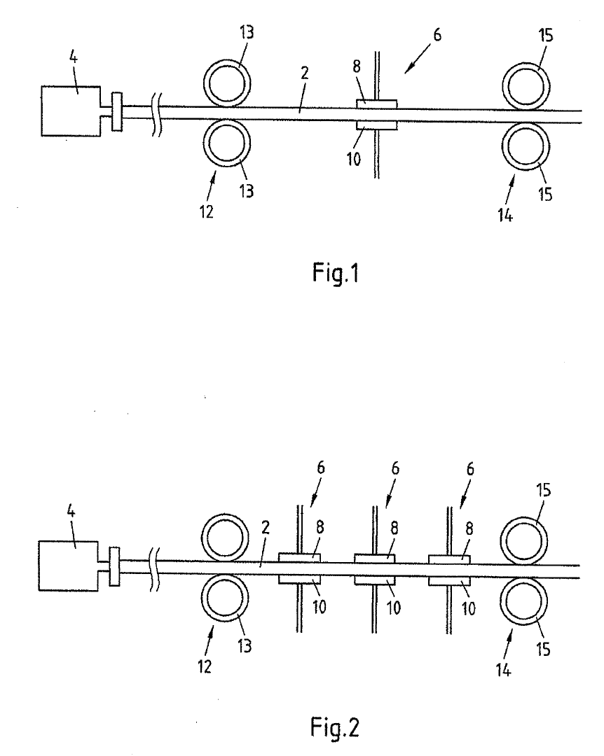

FIG. 1 shows a first embodiment of an invented apparatus for coating the inside wall surface of a continuous tube. Schematically indicated is a tube 2, which is connected to a gas inlet 4 for the introduction of a gas mixture into the said tube 2. In this arrangement, as an example, the gas source can be a cylinder, tank, capsule or the like. Further, an electrode unit 6 is provided in order to create an electrical field within the hollow space of tube 2.

Upon the application of a time-related, alternating voltage onto the two electrodes 8 and 10, a variable electric field within the tube 2 is created and thereby, the gas mixture within the tube is partially converted into a plasma. The additive or additives placed in the gas mixture undergo a chemical reaction and the product there from deposits itself as a superpositioned coating onto the surface of the inner wall of the said tubing 2. That is to say, the products of the reaction conform to the formation of a desired lining of inert material.

As FIG. 1 further demonstrates, provision has been made for a transport device 12 for advancing the tube. Likewise, provision has been made for transport device 14 for the retraction of the tube 2. In this way, the gas infeed equipment 4 remains stationary, and hence the tube 2 is shown in a broken elongation. The section of the tube 2 between the gas infeed equipment 4 and the electrode unit 6, as well as behind said equipment, can be appropriately interpositioned, that is, set in a transport structure to run forward and back as described above. Accordingly, transport devices 12 and 14 possess, respectively, two co-acting rollers 13 and 15, which permit the smooth travel of the tube 2. Instead of the rollers, it is it possible that conveyor bands or other known conveyor means be used.

FIG. 2 shows a second embodiment of the present invention, similar to FIG. 1, except that three electrode units 6 are provided. In principle, even more electrode units 6 can be so employed, but such construction would be dependent upon the needs of the current application and can remain optional.

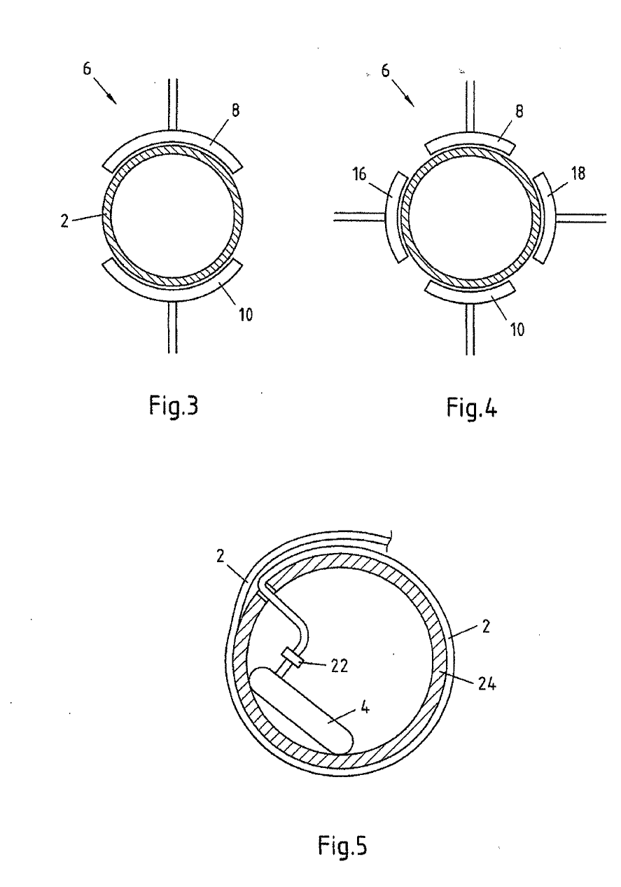

In FIG. 3 is illustrated an electrode unit 6 with two electrodes 8 and 10, which respectively, are circular in form to accommodate the rounded form of the tube 2. On this account, the two electrodes 8 and 10 are placed at an equal radial distance away from the outer side of the tube 2, and as a result, the electrical field so produced would generally be of uniform strength in the hollow space within the tube 2.

FIG. 4 shows an additional embodiment of the electrode unit, with four electrodes 8, 10, 16 and 18. This multiplicity of electrodes allows the production of another geometry of the electrical field within the hollow space of, for example, continuous tubing 2.

FIG. 5 depicts the tube 2, wound about a drum 20, which drum is shown in cross-section. This drum is for transport, storage, or inventory or the like of flexible tubing. Within the drum 20 is shown a gas cylinder 4 to which one end of the tube 2 is connected by a fitting 22. The tube 2 has made entry into the drum 20 through an appropriate wall fitting 24. The gas cylinder 4 turns in common with the drum 20 and can continually assure the feed of gas into the tube 2 as the tube is rolled on or off the drum.

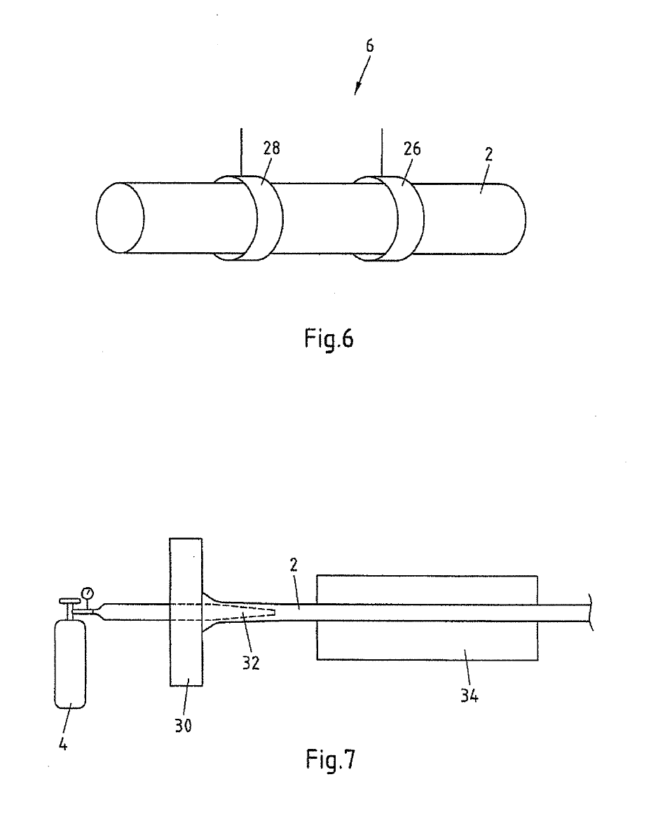

FIG. 6 brings to attention another variant of an electrode arrangement 6, wherein the electrodes 26 and 28 are not, as before, separated by a predetermined circumferential angle, but rather are axially displaced. Thus, when an alternating electrical field is produced by the electrodes 26 and 28, then an inner tube discharge in the axial direction occurs, which occupies a greater reactive zone within the tube 2 than otherwise experienced, such as in FIGS. 3, 4.

FIG. 7 shows the input of a mixture of gas and an additive(s) into a tube 2, which extends from an extruder 30. An extended calibration nozzle 32 is shown extending beyond the extruder 30. This nozzle 32 is pictured schematically connected to a gas cylinder 4, which represents a multiple connection to one or more gas mixture sources which are mutually coupled with one another. By means of this calibrated nozzle 32, gas mixture is forced into the currently emerging tube 2. The extruded tube 2 subsequently runs into a cooling apparatus 34, which stabilizes its shape. One of the previously described electrode 6 arrangements would be installed to the right, as one looks at the drawing, in order to allow the generation of a plasma in the hollow, continuous, geometric array, specifically, an interior space of the tube 2.

1. A method for the coating of an interior surface of a hollow, continuous, geometric array, wherein:
an at least one additive containing gas mixture is introduced into the tube,
a continuous tubing is linearly transported through an electric field of at least one electrode unit,
an alternating electrical voltage is applied to the at least one electrode unit,
in a zone within the continuous tubing and proximal to the at least one electrode unit, the gas mixture is at least partially converted into a plasma,
by means of the plasma, reaction products are produced out of the gas mixture from an additive or additives, and
the said reaction products deposit themselves on an inner wall surface of the continuous tubing and there consolidate into an inert lining.

2. A method in accord with claim 1, wherein a mixture of an additive or additives is added to the gas mixture.

3. A method in accord with claim 1, wherein the atmosphere in the continuous tubing prior to the introduction of the gas mixture is adjusted by purging with an additive-free, or an additive-poor gas mixture.

4. A method in accord with claim 3, wherein the inner wall surface of the continuous tubing is cleaned and activated by the creation of a plasma in an additive-free or additive-poor gas mixture.

5. A method in accord with claim 4, wherein the cleaning, and activation, is carried out in a separate operational step.

6. A method in accord with claim 3,
wherein the additive-free or additive-poor gas mixture is first introduced as a carrier gas without an additive, for the purpose of adjusting the atmosphere within the continuous tubing to an atmosphere of a desirable content and wherein subsequently thereto, the gas mixture containing an additive or additives in proper mix is introduced.

7. A method in accord with claim 1, wherein the plasma, with the aid of a microwave discharge or a barrier discharge is created.

8. A method in accord with claim 1,
wherein a plurality of electrode units is provided and
wherein a continuous geometrical array of tubing is transported through a plurality of electrode units.

9. A method in accord with claim 8, wherein more than one plasma zone are successively created.

10. A method in accord with claim 1, wherein the reaction product is deposited as a continuously unbroken surface.

11. A method in accord with claim 1, wherein the reaction product is deposited on at least one predetermined part of the inner wall surface.

12. A method in accord with claim 1, wherein the transported speed of the hollow, continuous geometric array passing through at least one electrode unit is adjusted to be less than a velocity of the gas mixture flow.

13. A method in accord with claim 1,
wherein the hollow, continuous geometric array is windingly rolled on a drum and
wherein in the neighborhood of an opening on said drum, the hollow, continuous geometric array is provided with a gas mixture supply.

14. A method in accord with claim 1,
wherein a the hollow, continuous geometric array is installed within an extrusion procedure, and
wherein following said extrusion procedure, the hollow continuous geometric array is directly transported through at least one electrode unit.

15. A method in accord with claim 14, wherein the gas mixture within the hollow, continuous geometric array is conducted through an extrusion conduit.

16. A method in accord with claim 1,
wherein the hollow continuous geometric array is subjected to a radiantly emitted cross-linking procedure, and
wherein, the gas mixture is conducted through a hardening cure procedure, and
wherein, following said hardening cure procedure, the hollow, continuous geometric array is run through at least one electrode unit.

17. A method in accord with claim 1, wherein, as a first step, a mixture of an inert gas or air is introduced into the gas mixture, and as a second step, additives of HMDSO and/or HMDSN are introduced into the gas mixture.

18. A method in accord with claim 1, wherein first a mixture of inert gas or air and second, additive(s) TMOS, TEOS, D3, D4 trialkoxyalkylsilane, or dialkoxydialkylsilane as well as a combination of these additives are introduced.

19. A method in accord with claim 1, wherein a mixture of acetylene and air is introduced.

20. A method in accord with claim 1, wherein a fluor-containing gas mixture is introduced.

21. A method in accord with claim 1, wherein a fluorocarbon type, fluorhydrocarbon containing gas mixture is introduced.

22. An apparatus for the coating of an inner surface of a hollow, continuous, geometric array by the execution of a method in accord with claim 1, wherein said method and apparatus are provided:
with a gas inlet apparatus for the feed of a gas mixture into the hollow, continuous, geometric array and
with at least one electrode unit for the establishment of an electrical field in the hollow, continuous, geometric array.

23. An apparatus in accord with claim 22, wherein at least one transport device, or a centralizing, calibration unit is provided for the purpose of axially displacing the hollow, continuous geometric array, and/or
at least one transport device is provided for the axial retraction of the hollow, continuous geometric array.

24. An apparatus in accord with claim 22, wherein a plurality of electrode units is provided.

25. An apparatus in accord with claim 22, wherein
the at least one electrode unit possesses two electrodes.

26. An apparatus in accord with claim 22, wherein
the electrode unit possesses at least two of ring type electrodes which circumferentially embrace the continuous geometric array and which are separated axially.

27. An apparatus in accord with claim 22, wherein
the hollow, continuous, geometric array, is wound upon a drum, and
by means of a coupling a connective end, which is located on a drum fitting is connected to the gas feed cylinder.
